(19) United States
(12) Patent Application Publication
(10) Pub. No.: US 2015/0255555 A1
(43) Pub. Date: Sep. 10, 2015

(54) METHODS OF FORMING A NON-PLANAR ULTRA-THIN BODY DEVICE

(71) Applicant: GLOBALFOUNDRIES INC., GRAND CAYMAN (KY)

(72) Inventors: Ruilong Xie, Niskayuna, NY (US); Ajey Poovannummoottil Jacob, Watervliet, NY (US); Michael Hargrove, Clinton Corners, NY (US); William J. Taylor, Jr., Clifton Park, NY (US)

(73) Assignee: GLOBALFOUNDRIES INC., GRAND CAYMAN (KY)

(21) Appl. No.: 14/197,686

(22) Filed: Mar. 5, 2014

(51) Int. Cl. H01L 29/423; H01L 29/66; H01L 29/78

(52) U.S. Cl. CPC H01L 29/42356; H01L 29/785; H01L 29/66795

(57) ABSTRACT

One illustrative method disclosed herein involves, among other things, forming a first epi semiconductor material on the exposed opposite sidewalls of a fin to thereby define a semiconductor body, performing at least one etching process to remove at least a portion of the substrate portion of the fin positioned between the first epi semiconductor materials positioned on the opposite sidewalls of the fin and to thereby define a back-gate cavity, forming a back-gate insulating material within the back-gate cavity and on the first epi semiconductor materials, forming a back-gate electrode on the back-gate insulation material within the back-gate cavity and forming a gate structure comprised of a gate insulation layer and a gate electrode around the semiconductor bodies.

### BACKGROUND OF THE INVENTION

1. Field of the Invention

Generally, the present disclosure relates to the manufacture of FET semiconductor devices, and, more specifically, to various methods of forming a non-planar ultra-thin body semiconductor device and the resulting device structures.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout, wherein so-called metal oxide field effect transistors (MOSFETs or FETs) represent one important type of circuit element that substantially determines performance of the integrated circuits. A conventional FET is a planar device that typically includes a source region, a drain region, a channel region that is positioned between the source region and the drain region, and a gate electrode positioned above the channel region. Current flow through the FET is controlled by controlling the voltage applied to the gate electrode. For example, for an NMOS device, if there is no voltage applied to the gate electrode, then there is no current flow through the NMOS device (ignoring undesirable leakage currents, which are relatively small). However, when an appropriate positive voltage is applied to the gate electrode, the channel region of the NMOS device becomes conductive, and electrical current is permitted to flow between the source region and the drain region through the conductive channel region.

To improve the operating speed of FETs, and to increase the density of FETs on an integrated circuit device, device designers have greatly reduced the physical size of FETs over the past decades. More specifically, the channel length of FETs has been significantly decreased, which has resulted in improving the switching speed and in lowering operation currents and voltages of FETs. However, decreasing the channel length of a FET also decreases the distance between the source region and the drain region. In some cases, this decrease in the separation between the source and the drain makes it difficult to efficiently inhibit the electrical potential of the source region and the channel from being adversely affected by the electrical potential of the drain. This is sometimes referred to as a so-called short channel effect, wherein the characteristic of the FET as an active switch is degraded.

In contrast to a FET, which has a planar structure, a so-called FinFET device has a three-dimensional (3D) structure. FIG. 1 is a perspective view of an illustrative prior art FinFET semiconductor device 10 that is formed above a semiconductor substrate 12 that will be referenced so as to explain, at a very high level, some basic features of a FinFET device 10. In this example, the FinFET device 10 includes three illustrative fins 14, a gate structure 16, sidewall spacers 18 and a gate cap layer 20. The gate structure 16 is typically comprised of a layer of gate insulating material (not separately shown), e.g., a layer of high-k insulating material or silicon dioxide, and one or more conductive material layers (e.g., metal and/or polysilicon) that serve as the gate electrode for the device 10. The fins 14 have a three dimensional configuration: a height 14H, a width 14W and a long-axis or axial length 14L. The axial length 14L corresponds to the direction of current travel in the device 10 when it is operational. The dashed line 14C depicts the long-axis or centerline of the fins 14. The portions of the fins 14 covered by the gate structure 16 are the channel regions of the FinFET device 10. In a conventional process flow, the portions of the fins 14 that are positioned outside of the spacers 18, i.e., in the source/drain regions of the device 10, may be increased in size or even merged together (a situation not shown in FIG. 1) by performing one or more epitaxial growth processes. The process of increasing the size of or merging the fins 14 in the source/drain regions of the device 10 is performed to reduce the resistance of source/drain regions and/or make it easier to establish electrical contact to the source drain regions. Even if an epi “merge” process is not performed, an epi growth process will typically be performed on the fins 14 to increase their physical size.

In the FinFET device 10, the gate structure 16 may enclose both sides and the upper surface of all or a portion of the fins 14 to form a tri-gate structure so as to use a channel having a three-dimensional structure instead of a planar structure. In some cases, an insulating cap layer (not shown), e.g., silicon nitride, is positioned at the top of the fins 14 and the FinFET device 10 only has a dual-gate structure (sidewalls only). Unlike a planar FET, in a FinFET device, a channel is formed perpendicular to a surface of the semiconducting substrate so as to reduce the physical size of the semiconductor device. Also, in a FinFET, the junction capacitance at the drain region of the device is greatly reduced, which tends to significantly reduce short channel effects. When an appropriate voltage is applied to the gate electrode of a FinFET device, the surfaces (and the inner portion near the surface) of the fins 14, i.e., the vertically oriented sidewalls and the top upper surface of the fin, form a surface inversion layer or a volume inversion layer that contributes to current conduction. In a FinFET device, the “channel-width” is estimated to be about two times (2×) the vertical fin-height of the fin 14 plus the width of the top surface of the fin 14, i.e., the fin width. Multiple fins can be formed in the same foot-print as that of a planar transistor device. Accordingly, for a given plot space (or foot-print), FinFET devices tend to be able to generate significantly higher drive current density than planar transistor devices. Additionally, the leakage current of FinFET devices after the device is turned “OFF” is significantly reduced as compared to the leakage current of planar FETs, due to the superior gate electrostatic control of the “fin” channel on FinFET devices. In short, the 3D structure of a FinFET device is a superior MOSFET structure as compared to that of a planar FET, especially in the 20 nm CMOS technology node and beyond. The gate structures 16 for such FinFET devices 10 may be manufactured using so-called “gate-first” or “replacement gate” (gate-last) manufacturing techniques.

The above-described FET and FinFET devices may be formed in bulk semiconductor substrates (e.g., silicon) or they may be formed using semiconductor-on-insulator (SOI) technology, wherein the devices are formed in a single crystal semiconductor material on top of an insulating layer. The insulating layer is typically a so-called buried oxide layer (BOX), which, in turn, is positioned above a silicon wafer. Advances in integrated circuit manufacturing are typically associated with decreasing feature sizes, namely the decrease in the gate length of the devices. The focus today is on the fabrication of FET devices with gate lengths of 25 nm, and less. The main candidates for reaching such short gate lengths are SOI devices, either planar devices or non-planar devices. It is known from device scaling theory that, for proper functioning, the device body above the channel region has to be scaled down in proportion to the gate length of the device. It is expected that, for planar SOI devices, the body thickness may have to be about ⅓ to ¼ of the gate length of the device. While, for non-planar FET devices, such as FinFet devices, the body thickness may have to be about ½ to ⅓ of the gate length. In general, the thinner the device body above the channel, the better the electrostatic control characteristics of the device, which results in reduced leakage currents. While the above statements reflect desirable aspects of such thin body devices in terms of electrical performance, manufacturing such devices is very difficult and presents many challenges. The ultimate for device designers is to manufacture such thin body devices using techniques that are reliable and suitable for large scale production. More specifically, a traditional planar UTTB device has good electrostatic control and back gate control, but bad area scaling capability, while a traditional FinFET device has good electrostatic control and area scaling capability, but not good back gate control. The present disclosure is, in general, directed to a non-planar UTTB device, which has good electrostatic control, good back gate control, and good scaling capability.

The present disclosure is directed to various methods of forming a non-planar ultra-thin body semiconductor device and the resulting device structures that may solve or reduce one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming a non-planar ultra-thin body semiconductor device and the resulting device structures. One illustrative method disclosed herein involves, among other things, forming a plurality of trenches in the substrate so as to define a fin comprised of the material of the substrate, forming a recessed first layer of insulating material in the trenches so as to expose a portion, but not all, of the sidewalls of the fin, forming a first epi semiconductor material on the exposed opposite sidewalls of the fin to thereby define a semiconductor body, forming a second layer of insulating material above the recessed first layer of insulating material, after forming the second layer of insulating material, performing at least one etching process to remove at least a portion of the substrate portion of the fin positioned between the first epi semiconductor materials positioned on the opposite sidewalls of the fin and to thereby define a back-gate cavity, forming a back-gate insulating material within the back-gate cavity and on the first epi semiconductor materials exposed by the formation of the back-gate cavity, forming a back-gate electrode on the back-gate insulation material within the back-gate cavity and forming a gate structure comprised of a gate insulation layer and a gate electrode around the semiconductor body.

One illustrative UTTB device disclosed herein includes, among other things, a back-gate electrode positioned on a semiconductor substrate, wherein the back-gate electrode is comprised of a first semiconductor material and has sidewalls, first and second layers of back-gate insulation material positioned on opposite sidewalls of the back-gate electrode, first and second semiconductor body regions positioned on and in contact with the first and second layers of back-gate insulation material, respectively, the first and second semiconductor body regions being comprised of an epi semiconductor material, a gate structure positioned around the first and second semiconductor body regions, wherein the gate structure comprises a front gate insulation layer that contacts the first and second semiconductor body regions and a gate electrode that contacts the front gate insulation layer.

### BRIEF DESCRIPTION OF THE DRAWINGS

The disclosure may be understood by reference to the following description taken in conjunction with the accompanying drawings, in which like reference numerals identify like elements, and in which:

FIG. 1 depicts an illustrative example of a prior art FinFET device with various features identified for reference purposes; and

FIGS. 2A-2N depict various illustrative methods of forming the illustrative non-planar ultra-thin body semiconductor devices and the resulting device structures.

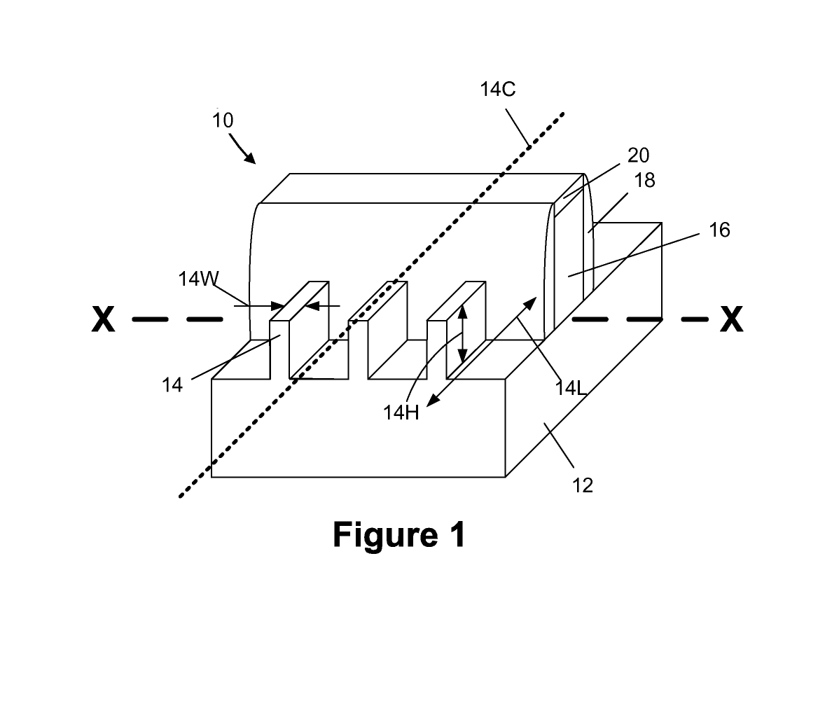

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to various methods of forming a non-planar ultra-thin body semiconductor device and the resulting device structures. The method disclosed herein may be employed in manufacturing either an N-type device or a P-type device, and the gate structure of such devices may be formed using either so-called “gate-first” or “replacement gate” (“gate-last”) techniques. As will be readily apparent to those skilled in the art upon a complete reading of the present application, the present method is applicable to a variety of devices, including, but not limited to, logic devices, memory devices, etc. With reference to the attached figures, various illustrative embodiments of the methods and devices disclosed herein will now be described in more detail.

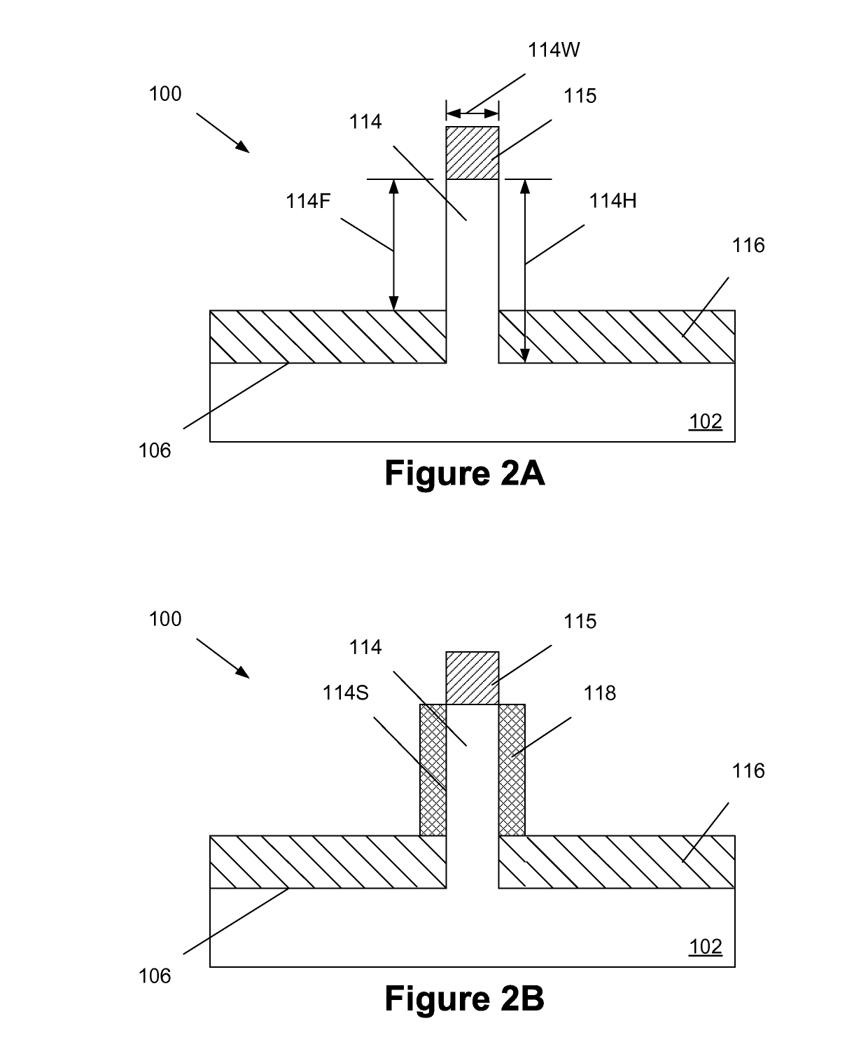

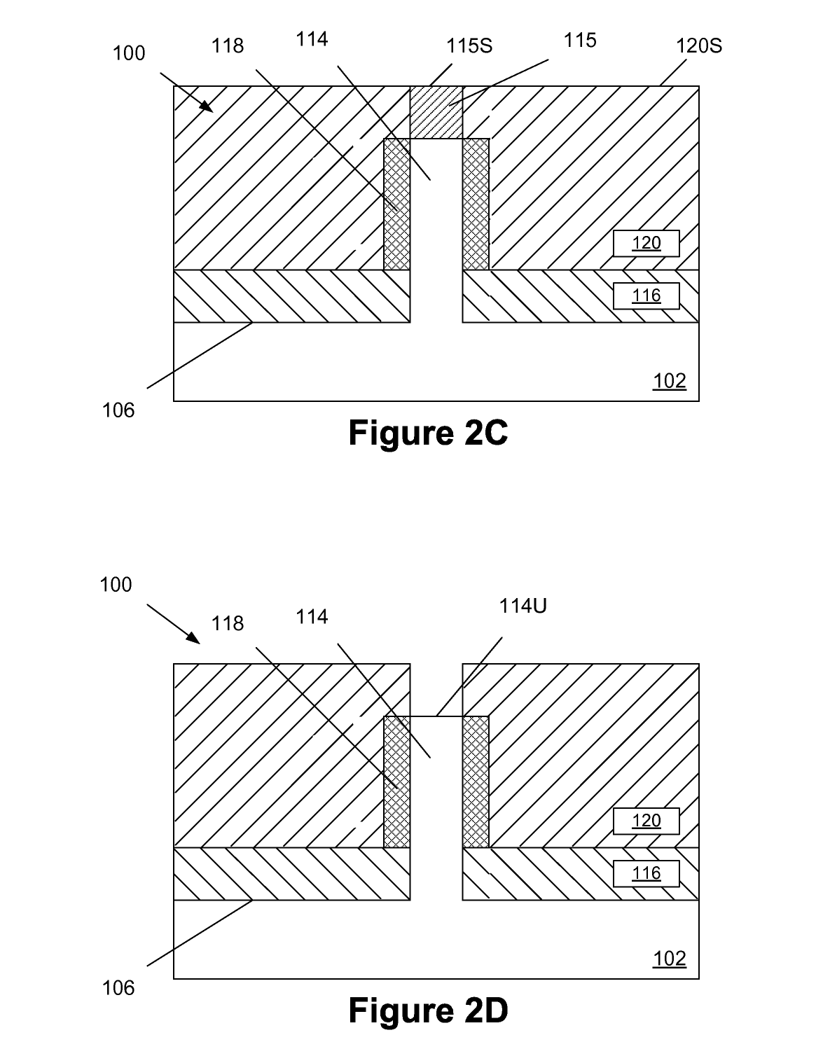

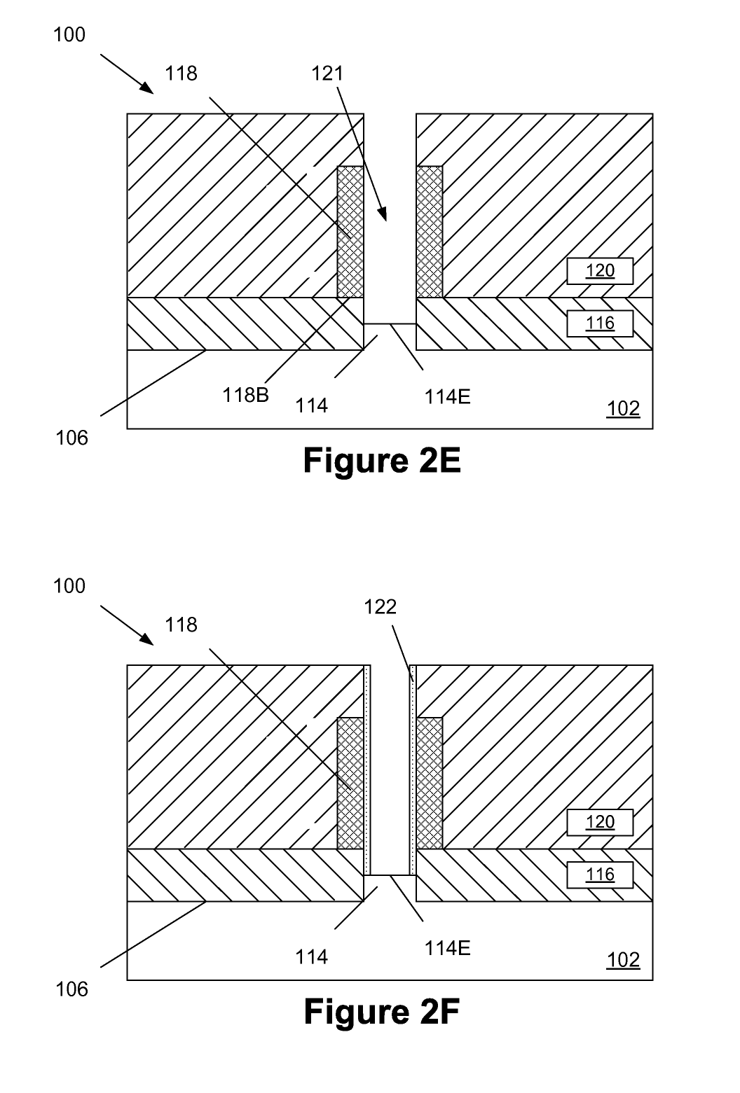

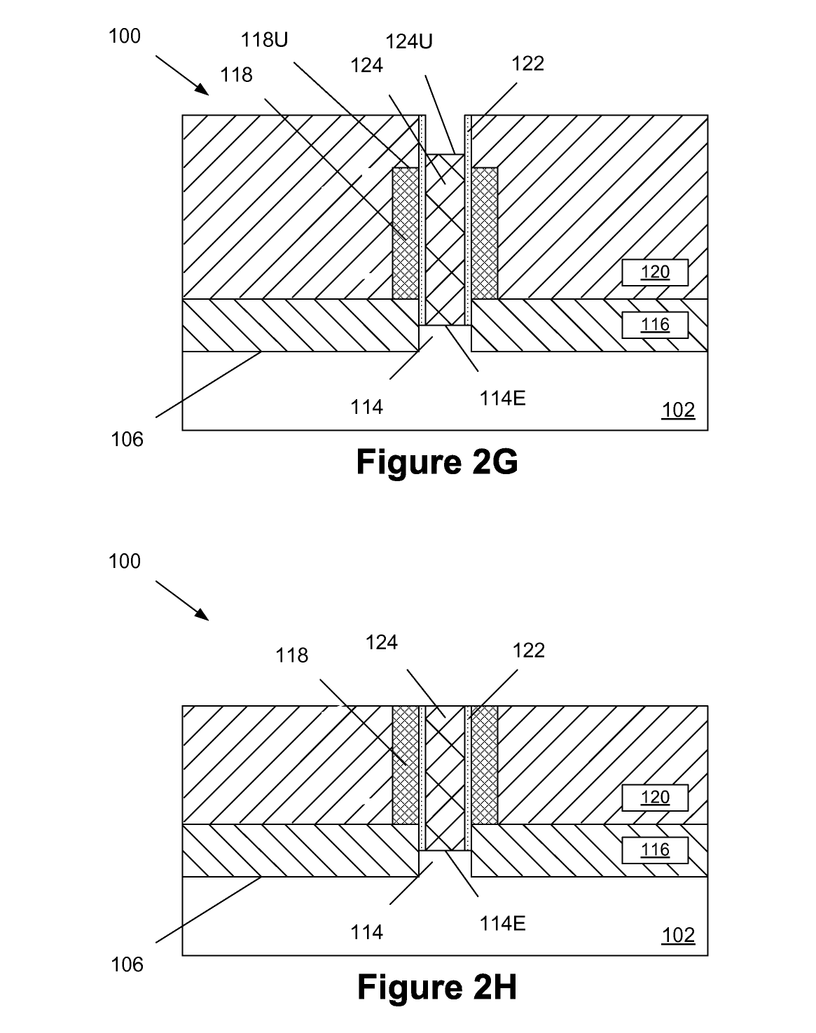

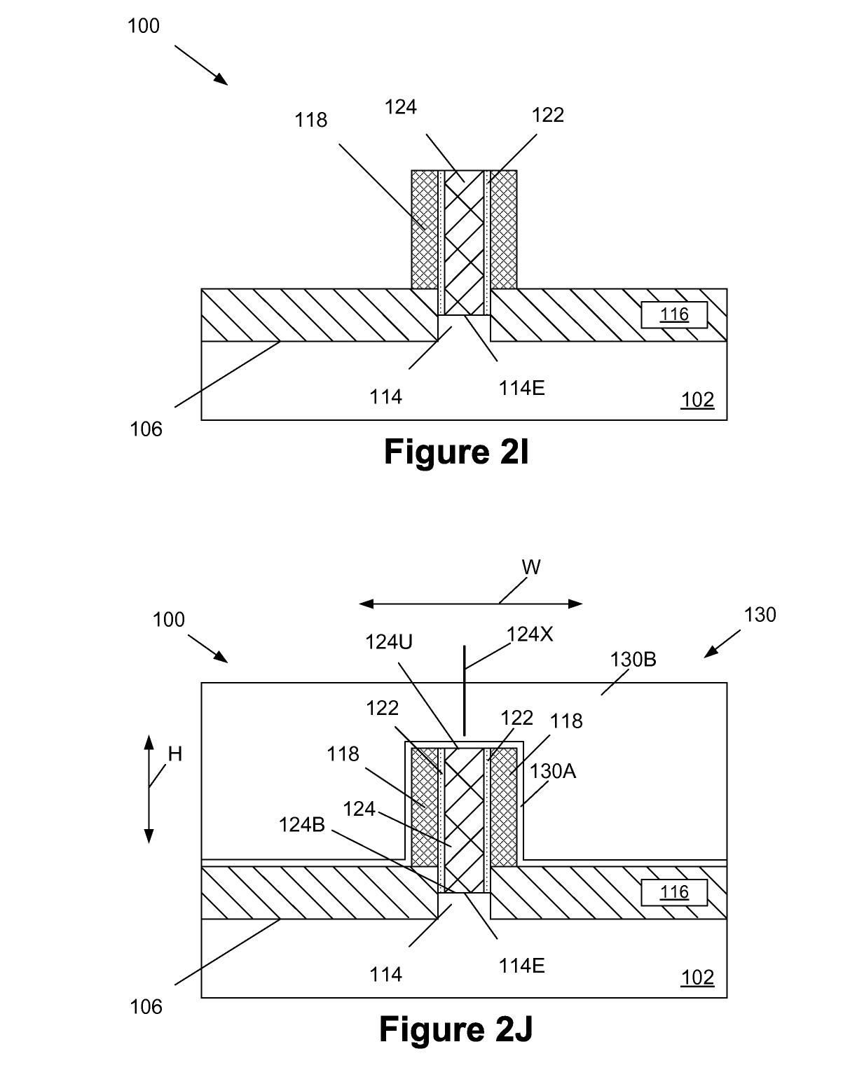

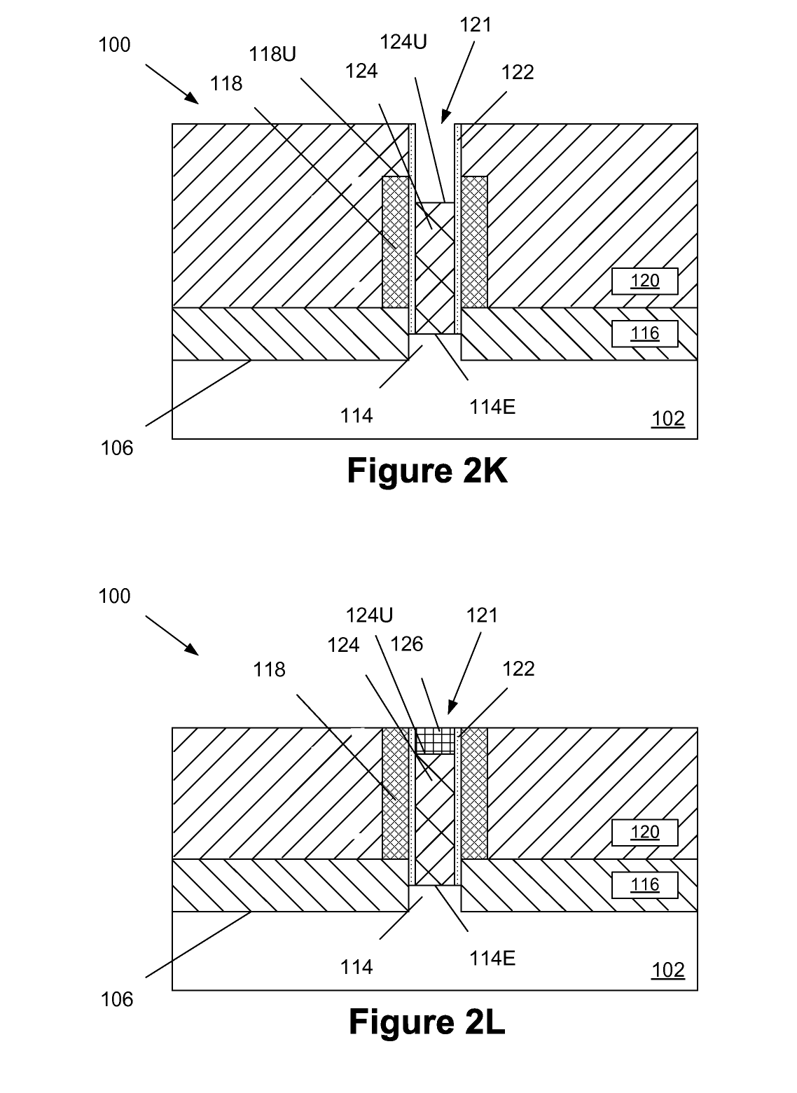

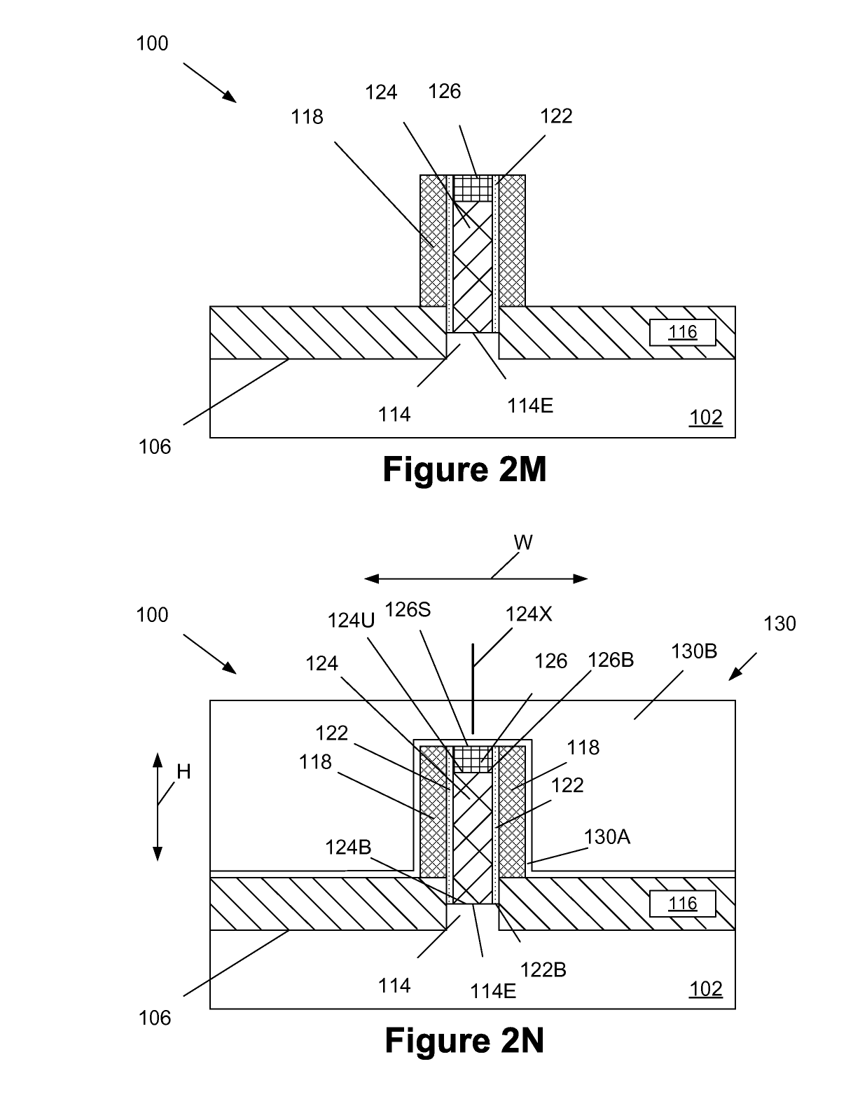

FIGS. 2A-2N depict illustrative embodiments of the various methods disclosed herein of UTTB devices, wherein the UTTB device 100 is formed on a bulk semiconducting substrate 102. FIG. 2A is a simplified view of an illustrative UTTB device 100 at an early stage of manufacturing. As will be recognized by those skilled in the art after a complete reading of the present application, the UTTB device 100 described herein may be either an N-type device or a P-type device. In this illustrative embodiment, the substrate 102 has a bulk semiconducting material configuration. The substrate 102 may be made of silicon or it may be made of materials other than silicon. Thus, the terms “substrate” or “semiconductor substrate” should be understood to cover all forms of all semiconductor materials.

FIG. 2A depicts UTTB device 100 after several process operations were performed. First an illustrative patterned trench-patterning hard mask layer 115 was formed above the substrate 102. Thereafter, one or more etching processes were performed through the trench-patterning hard mask layer 115 to define a plurality of fin-formation trenches 106 in the substrate 102 so as to thereby form the illustrative fin 114. The height 114H and width 114W of the fin 114 may vary depending upon the particular application. In one example, the overall fin height 114H may fall within the range of about 100-200 nm. Of course, as will be appreciated by those skilled in the art after a complete reading of the present application, any desired number of fins and UTTB devices can be formed using the methods disclosed herein. Next, the trenches 106 were overfilled with an insulating material 116 and a planarization process, e.g., a CMP process or an etch-back process, was performed to planarize the upper surface of the layer of insulating material 116 with the upper surface of the trench-patterning hard mask layer 115. Thereafter, a recess etching process was performed to reduce the thickness of the layer of insulating material 116 and to set the exposed height 114F, e.g., 20-60 nm, of the fin 114 at this point in the process flow. The amount of the layer of insulating material 116 that remains after the recessing (“etch-back”) process is performed may vary depending upon the particular application, e.g., 10-100 nm.

In the illustrative example depicted in the attached figures, the fin-formation trenches 106 and the initial fins 114 are all of a uniform size and shape. However, such uniformity in the size and shape of the fin-formation trenches 106 and the initial fins 114 is not required to practice at least some aspects of the inventions disclosed herein. In the example depicted herein, the fin-formation trenches 106 are depicted as having been formed by performing a plurality of anisotropic etching processes. In some cases, the fin-formation trenches 106 may have a reentrant profile near the bottom of the fin-formation trenches 106. To the extent the fin-formation trenches are formed by performing a wet etching process, the fin-formation trenches 106 may tend to have a more rounded configuration or non-linear configuration as compared to the generally linear configuration of the fin-formation trenches 106 that are formed by performing an anisotropic etching process. In other cases, the fin-formation trenches 106 may be formed in such a manner that the initial fins 114 have a tapered cross-sectional configuration (wider at the bottom than at the top at this point in the process flow). Thus, the size and configuration of the fin-formation trenches 106, as well as the fins 114, and the manner in which they are made, should not be considered a limitation of the present invention.

The trench-patterning hard mask layer 115 is intended to be representative in nature as it may be comprised of a variety of materials, such as, for example, a photoresist material, silicon nitride, silicon oxynitride, etc. Moreover, the trench-patterning hard mask layer 115 may be comprised of multiple layers of material, such as, for example, a so-called silicon dioxide pad oxide layer (not shown) formed on the substrate and a so-called silicon nitride pad nitride layer (not shown). The trench-patterning hard mask layer 115 may be formed by depositing the layer(s) of material that comprise the trench-patterning hard mask layer 115 and thereafter directly patterning the trench-patterning hard mask layer 115 using known photolithography and etching techniques. Alternatively, the trench-patterning hard mask layer 115 may be formed by using known sidewall image transfer techniques. Thus, the particular form and composition of the trench-patterning hard mask layer 115 and the manner in which it is made should not be considered a limitation of the present invention. In the case where the trench-patterning hard mask layer 115 is comprised of one or more hard mask layers, such layers may be formed by performing a variety of known processing techniques, such as a chemical vapor deposition (CVD) process, an atomic layer deposition (ALD) process, an epitaxial deposition process (EPI), or plasma enhanced versions of such processes, and the thickness of such a layer(s) may vary depending upon the particular application.

The layer of insulating material 116 discussed herein may be comprised of a variety of different materials, such as, for example, silicon dioxide, silicon nitride, silicon oxynitride or any other dielectric material in common use in the semiconductor manufacturing industry, etc., or multiple layers thereof, etc., and it may be formed by performing a variety of techniques, e.g., chemical vapor deposition (CVD), etc.

FIG. 2B depicts the UTTB device 100 after a very thin epitaxially deposited/grown semiconductor material 118 was formed on the exposed, opposite sidewall portions 114S of the fin 114. As will be appreciated by those skilled in the art after a complete reading of the present application, the spaced-apart regions of the epi semiconductor material 118 will serve as the thin semiconductor body for the completed UTTB device 100 where the channel region for the device will form during operation. Note that, in this embodiment, the epi semiconductor material 118 has a substantially uniform thickness (+/−10%) on the sidewalls 114S, which may fall within the range of about 3-6 nm in one illustrative embodiment. The epi semiconductor material 118 may be formed by performing a traditional epitaxial deposition/growth process. The epi semiconductor material 118 may be comprised of a variety of different materials, e.g., silicon, silicon/germanium (SiₓGe₁₋ₓ), germanium, silicon phosphorous (SiP), silicon carbon phosphorous (SiCP), germanium tin (GeSn), Si:B, SiGe:B, SiGe:P, SiGe:As, etc. In one illustrative embodiment, the epi semiconductor material 118 may be made of a material that may be selectively etched relative to the fin 114 material, but such a situation is not required in all applications.

FIG. 2C depicts the UTTB device 100 after the trenches 106 were overfilled with another layer of insulating material 120 and a planarization process, e.g., a CMP process or an etch-back process, was performed to planarize the upper surface 120S of the layer of insulating material 120 with the upper surface 115S of the trench-patterning hard mask layer 115. The layer of insulating material 120 may be made of the same material as that of the layer of insulating material 116, or it may be made of a different material.

FIG. 2D depicts the UTTB device 100 after one or more etching processes were performed to remove the trench-patterning hard mask layer 115 and thereby expose the upper surface 114U of the fin 114.

FIG. 2E depicts the UTTB 100 after one or more selective etching processes were performed to remove a desired amount of the fin 114 relative to the epi semiconductor material 118 and the layer of insulating material 120. This process operation removes a sufficient amount of the fin 114 such that its post-etch upper surface 114E of the remaining fin 114 is positioned at a level that is below the level of the bottom surface 118B of the epi semiconductor material 118, e.g., by a distance that falls within the range of about 5-50 nm. This etching process results in the formation of a back-gate cavity 121. In the case where the epi semiconductor material 118 may be selectively etched relative to the fin material, the etching process may be performed with an etch chemistry where there is a relatively high degree of etch selectivity between the fin material, i.e., the substrate material 102, and the epi semiconductor material 118. For example, in the case where the substrate 102 is made of silicon and the epi semiconductor material 118 is made of silicon-germanium, the etch process may be an isotropic or anisotropic etching process that is performed using, for example, a KOH mixture (30% KOH by weight in water) at 80° C. In another embodiment where the materials of the fin 114 and the epi semiconductor material 118 are not readily selectively etchable relative to one another, i.e., where there is very little etch selectivity between the two materials, the structure depicted in FIG. 2E may be achieved by performing an anisotropic etching process.

FIG. 2F depicts the UTTB device 100 after (a) a layer of back-gate insulating material 122 was conformably deposited across the substrate 102 and in the back-gate cavity 121 on the regions of epi semiconductor material 118 and (b) an anisotropic etching process was performed on the layer of back-gate insulating material 122 so as to remove the horizontally oriented portions of the insulating material 122. Thus, after these process operations are performed, the layer of back-gate insulating material 122 is positioned on the sidewalls of the back-gate cavity 121 and on the epi semiconductor materials 118, i.e., the thin semiconductor body of the device 100. As will be appreciated by those skilled in the art after a complete reading of the present application, the layer of back-gate insulating material 122 will serve as the gate insulation layer for the back-gate electrode (yet to be formed) of the UTTB device 100 that will ultimately be formed in the back-gate cavity 121. The back-gate insulation layer 122 may be comprised of a variety of different materials, such as, for example, silicon dioxide, silicon nitride, silicon oxynitride, a high-k material (k greater than 10, where k is the relative dielectric constant), hafnium oxide, aluminum oxide, etc., it may have a thickness that falls within the range of about 1-3 nm and it may be initially formed by performing a conformal ALD or CVD deposition process.

FIG. 2G depicts the UTTB device 100 after another epi semiconductor material 124 was formed in the back-gate cavity 121 on the recessed edge 114E of the fin 114. As will be appreciated by those skilled in the art after a complete reading of the present application, the epi semiconductor material 124 will serve as a back-gate electrode for the completed UTTB device 100. In one embodiment, when processing is completed, the epi semiconductor material 124 has an upper surface 124U that is positioned above the upper surface 118U of the epi semiconductor material 118 by a distance of about 5-30 nm. The epi semiconductor material 124 may be formed by performing a traditional epitaxial deposition/growth process. The epi semiconductor material 124 may be comprised of a variety of different materials, such as the ones identified above for the epi semiconductor material 118. The epi semiconductor material 124 may be sufficiently doped with either an N-type or P-type dopant depending upon the device 100 under construction such that the epi semiconductor material 124 is a conductive material. In one particular embodiment, the epi semiconductor material 124 may be a heavily doped silicon material. The structure depicted in FIG. 2G may be the result of controlling the epi deposition process such that the epi deposition process is stopped once the epi semiconductor material 124 is formed such that the upper surface 124U is in the desired location. Alternatively, the epi deposition process may be performed until such time as the back-gate cavity 121 is substantially filled with the epi material. Thereafter, a recess etching process may be performed to remove the desired amount of the epi material 124 until the upper surface 124U of the epi material 124 is at the desired location. In another embodiment, the material 124 may simply be deposited in the back-gate cavity 121, e.g., the material 124 may simply be a deposited heavily doped polysilicon material. This will generate the same structure after CMP described below in FIG. 2H.

FIG. 2H depicts the UTTB device 100 after one or more process operations, e.g., one or more chemical mechanical polishing (CMP) processes, were performed to planarize the layer of insulating material 120, the layer of insulating material 122 and the epi semiconductor materials 118, 124.

FIG. 2I depicts the UTTB device 100 after an etch-back process was performed to recess at least a portion of the layers of insulating material 120, 116 to the desired level and thereby expose the desired amount of the epi material 118, i.e., the body of the device 100. In the depicted example, substantially all of the layer of insulating material 120 has been removed.

FIG. 2J depicts the UTTB device 100 after a schematically depicted gate structure 130 was formed on the device 100. The gate structure 130 will serve as the front gate of the UTTB device 100. The gate structure 130 may be formed using well-known gate-first or replacement-gate (gate-last) techniques. The gate structure 130 that is described herein is intended to be representative in nature of any gate structure that may be formed on semiconductor devices using any type of technique. Of course, the materials of construction used for the gate structure 130 on a P-type device may be different than the materials used for the replacement gate structure 130 on an N-type device. In one illustrative embodiment, the schematically depicted materials for the gate structure 130 include an illustrative gate insulation layer 130A and an illustrative gate electrode 130B. The gate insulation layer 130A may be comprised of a variety of different materials, such as, for example, silicon dioxide, a so-called high-k (k greater than 10) insulation material (where k is the relative dielectric constant), etc. Similarly, the gate electrode 130B for the gate structure 130 may also be made of a variety of conductive materials, such as polysilicon or one or more metal layers that act as the gate electrode. At the point of fabrication depicted in FIG. 2J, traditional manufacturing operations may be performed to complete the formation of the UTTB device 100. For example, if desired, additional epi semiconductor material (not shown) may be formed in the source/drain regions of the device 100. Thereafter, contacts to the source/drain regions and the gate electrode 130B may be formed and multiple metallization layers may then be formed above the device 100 using traditional techniques.

FIGS. 2K-2N depict an alternative process flow. In this alternative process flow, the processing sequence performed up to the point depicted in FIG. 2F is the same as noted above. At the point of processing depicted in FIG. 2K, the epi semiconductor material 124 is formed in the back-gate cavity 121 such that its upper surface 124U is positioned below the upper surface 118U of the epi semiconductor material 118, by a distance of about 5-20 nm. In this embodiment, as before, the epi semiconductor material 124 may be formed by performing a traditional epitaxial deposition/growth process. The structure depicted in FIG. 2K may be the result of controlling the epi deposition process such that the epi deposition process is stopped once the epi semiconductor material 124 is formed such that the upper surface 124U of the epi material 124 is in the desired location. Alternatively, the epi deposition process may be performed until such time as the back-gate cavity 121 is substantially filled with the epi material 124. Thereafter, a recess etching process may be performed to remove the desired amount of the epi material 124 until the upper surface 124U of the epi material 124 is at the desired location, i.e., below the upper surface 118U of the epi semiconductor material 118, as shown in FIG. 2K. As will be appreciated by those skilled in the art after a complete reading of the present application, in this embodiment as well as the previous embodiment, the epi semiconductor material 124 will serve as a back-gate electrode for the completed UTTB device 100. As before, in another embodiment, the material 124 may simply be deposited in the back-gate cavity 121, e.g., the material 124 may simply be a deposited heavily doped polysilicon material that is subsequently etched back to the desired height level.

FIG. 2L depicts the UTTB device 100 after an illustrative cap layer 126 has been formed in the remaining portions of the back-gate cavity 121 on the upper surface 124U of the epi semiconductor material 124. The cap layer 126 may be formed by depositing a layer of the cap material, e.g., silicon nitride, so as to over-fill the remaining portions of the back-gate cavity 121 above the epi semiconductor material 124, and thereafter performing a CMP process to remove portions of the layer of cap material positioned above the surface of the layer of insulating material 120. The vertical thickness of the cap layer 126 may vary depending upon the particular application, e.g., 5-15 nm. The CMP operation was performed to planarize the layer of insulating material 120, the layer of insulating material 122 and the epi semiconductor materials 118, 124.

FIG. 2M depicts the UTTB device 100 after an etch-back process was performed to recess at least a portion of the layers of insulating material 120, 116 to the desired level and thereby expose the desired amount of the epi material 118. In the depicted example, substantially all of the layer of insulating material 120 has been removed.

FIG. 2N depicts the UTTB device 100 after the above-described and schematically depicted gate structure 130 was formed on the device 100.

Various novel aspects of the novel UTTB devices 100 disclosed herein will now be discussed with reference to FIGS. 2J and 2N. As can be seen in the cross-sectional views in these drawings, the UTTB devices disclosed herein are 3D devices having a height (in the direction H), a width (in the direction W, which corresponds to the gate width direction of the device) and a length (in the direction into and out of the drawing page, which corresponds to the gate length direction or current transport direction of the device). In the embodiment shown in FIG. 2J, the UTTB device is comprised of the back-gate electrode 124 that is positioned between two layers of back-gate insulating material, semiconductor body regions 118 positioned on the back-gate insulating materials 122, front gate insulating materials 130A positioned on the semiconductor body regions 118, and front gate electrode materials 130B positioned on the front gate insulating materials 130A. In the embodiment shown in FIG. 2J, the bottom surface 124B of the back-gate electrode 124 abuts and engages the substrate/fin 102/114, while the upper surface 124U of the back-gate electrode 124 abuts and engages the front gate insulating material 130A. In the embodiment shown in FIG. 2N, the cap layer 126 has been added relative to the device shown in FIG. 2J. Thus, for the device shown in FIG. 2N, the bottom surface 124B of the back-gate electrode 124 abuts and engages the substrate/fin 102/114, the upper surface 124U of the back-gate electrode 124 abuts and engages the bottom surface 126B of the cap layer 126 and the upper surface 126S of the cap layer 126 abuts and engages the front gate insulating material 130A. In both of the devices, when viewed in the cross-sections depicted in FIGS. 2J and 2N, the back-gate electrode 124 is taller (in the direction H) than it is wide (in the direction W). Thus, the back-gate electrode 124 has a long axis 124X (in this view) that is substantially normal to a horizontal reference plane, such as the upper surface of the starting substrate material 102 before the trenches 106 were formed. Simply stated, the UTTB devices disclosed herein include an upstanding back-gate electrode 124 positioned between two laterally spaced-apart (in the direction W) semiconductor body regions 118, with back-gate insulating materials 122 positioned therebetween. The devices 100 also include front gate insulating materials formed on the semiconductor body regions 118 and a front gate electrode material 130B positioned on the front gate insulating materials 130A. Also note that the bottom surface of the semiconductor body regions 118 abut and engage a layer of the insulating material, e.g., 116, formed in the trenches 106, and that the bottom surface 122B (see FIG. 2N) abuts and engages the substrate 102/fin 114. Also note that a portion of the back-gate insulating materials 122 positioned between the layer of insulating material 116 and the back-gate electrode 124 abuts both of those structures.

As will be appreciated by those skilled in the art after a complete reading of the present application, the illustrative UTTB devices and methods disclosed herein provide distinct advantages relative to UTTB devices in the prior art in terms of producing UTTB devices with better electrical characteristics, e.g., less leakage currents, and ones that may be readily manufactured with higher device densities, thereby saving valuable plot space on a substrate. The presence of the back-gate electrode (124) allows for controlling the threshold voltage of the device by back-biasing the back-gate electrode. The addition of the cap layer 126 (see FIG. 2L) tends to reduce the capacitance between the back-gate electrode 124 and the gate electrode 130B.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

What is claimed:

1. A method of forming a UTTB device in and above a semiconductor substrate, comprising:
forming a plurality of trenches in the substrate so as to define a fin comprised of the material of said substrate, said fin having sidewalls;
forming a recessed first layer of insulating material in said trenches so as to expose a portion, but not all, of said sidewalls of said fin;
forming a first epi semiconductor material on the exposed opposite sidewalls of said fin to thereby define a semiconductor body;
forming a second layer of insulating material above said recessed first layer of insulating material;
after forming said second layer of insulating material, performing at least one etching process to remove at least a portion of the substrate portion of said fin positioned between said first epi semiconductor materials positioned on said opposite sidewalls of said fin and to thereby define a back-gate cavity;
forming a back-gate insulating material within said back-gate cavity and on said first epi semiconductor materials exposed by the formation of said back-gate cavity;
forming a back-gate electrode on said back-gate insulation material within said back-gate cavity; and
forming a gate structure comprised of a gate insulation layer and a gate electrode around said semiconductor body.

2. The method of claim 1, wherein said substrate material is silicon and said first epi semiconductor material is one of silicon, silicon/germanium (SiₓGe₁₋ₓ), germanium, silicon phosphorous (SiP), silicon carbon phosphorous (SiCP), germanium tin (GeSn), Si:B, SiGe:B, SiGe:P, or SiGe:As.

3. The method of claim 1, wherein forming said back-gate insulating material within said back-gate cavity and on said first epi semiconductor materials exposed by the formation of said back-gate cavity comprises:
conformably depositing a layer of said back-gate insulating material in said back-gate cavity; and
performing an anisotropic etching process to remove horizontally positioned portions of said layer of back-gate insulating material.

4. The method of claim 1, wherein forming said back-gate electrode on said back-gate insulation material within said back-gate cavity comprises forming said back-gate electrode such that its upper surface is positioned at a level that is above the level of an upper surface of said first epi semiconductor material.

5. The method of claim 1, wherein forming said back-gate electrode on said back-gate insulation material within said back-gate cavity comprises forming said back-gate electrode such that its upper surface is positioned at a level that is below the level of an upper surface of said first epi semiconductor material.

6. The method of claim 5, further comprising forming a cap layer within said back-gate cavity and on said upper surface of said back-gate electrode.

7. The method of claim 1, wherein forming said back-gate electrode on said back-gate insulation material within said back-gate cavity comprises performing an epitaxial deposition process to form said back-gate electrode.

8. The method of claim 1, wherein forming said gate structure comprises forming a final gate structure for the device using a gate-first processing technique or forming a sacrificial gate structure using a gate-last technique.

9. A UTTB device having a gate structure and a gate width direction, comprising:
a back-gate electrode positioned on a semiconductor substrate, said back-gate electrode, when viewed in a cross-section taken through said gate structure in said gate width direction, having a bottom surface that abuts and engages said substrate, wherein said back-gate electrode is comprised of a first semiconductor material and sidewalls;
first and second layers of back-gate insulation material positioned on opposite sidewalls of said back-gate electrode;
first and second semiconductor body regions positioned on and in contact with said first and second layers of back-gate insulation material, respectively, said first and second semiconductor body regions being comprised of an epi semiconductor material; and
a gate structure positioned around said first and second semiconductor body regions, wherein said gate structure comprises a front gate insulation layer that contacts said first and second semiconductor body regions and a gate electrode that contacts said front gate insulation layer.

10. The device of claim 9, wherein an upper surface of said back-gate electrode abuts and engages said front gate insulation layer.

11. The device of claim 10, wherein an upper surface of each of said first and second semiconductor body regions abuts and engages said front gate insulation layer.

12. The device of claim 9, further comprising a cap layer positioned on an upper surface of said back-gate electrode, wherein an upper surface of said cap layer abuts and engages said front gate insulation layer.

13. The device of claim 12, wherein an upper surface of each of said first and second semiconductor body regions abuts and engages said front gate insulation layer.

14. The device of claim 9, wherein a bottom surface of each of said first and second semiconductor body regions abuts and engages an upper surface of a layer of insulating material.

15. The device of claim 14, wherein a portion of each of said first and second layers of back-gate insulation material abuts and engages a side surface of said layer of insulating material.

16. The device of claim 9, wherein said first semiconductor material and said epi semiconductor material are made of the same material.

17. The device of claim 9, wherein said first semiconductor material and said epi semiconductor material are made of different materials.

18. The device of claim 9, wherein said first semiconductor material is an epi semiconductor material.
